(19) United States
(12) Patent Application Publication
(10) Pub. No.: US 2003/0079334 A1
(43) Pub. Date: May 1, 2003

(54) Magnetic homogeneity design method

(76) Inventors: Minfeng Xu, Florence, SC (US); Xianrui Huang, Florence, SC (US); Michael Robert Eggleston, Florence, SC (US); Jinhua Huang, Florence, SC (US); Bu-Xin Xu, Florence, SC (US)

Correspondence Address: WILLIAM COLLARD, COLLARD & ROE, P.C., 1077 NORTHERN BOULEVARD, ROSLYN, NY, 11576, US

(21) Appl. No.: 09/682,880

(22) Filed: Oct. 29, 2001

(51) Int. Cl. H01F 7/06; G01R 1/00; H01L 39/24

(52) U.S. Cl. 29/607; 29/606; 29/593; 29/599

(57) ABSTRACT

A method is provided of designing a magnetic resonance imaging magnet. At least one correction coil is positioned about the axial bore of the magnet which receives patients. The correction coil is used in the design process to reduce lower order harmonics generated by the magnet. Homogeneity of the magnetic field is thereby improved at selected volumes around the magnet.

### BACKGROUND OF THE INVENTION

1. Field of the Invention

The present invention relates to magnets for magnetic resonance. More particularly, a design method is provided for producing magnets for magnetic resonance imaging.

2. The Prior Art

A number of procedures for designing magnets for magnetic resonance systems are known. For example, U.S. Pat. Nos. 5,818,319 and 6,084,497 to Crozier et al. and U.S. Pat. No. 4,800,354 to Laskaris relate to such design procedures.

Magnetic resonance imaging (MRI) magnets are designed with very high homogeneity requirements. During the design process, a number of field coils are placed in selected locations. The field coils include main coils that provide the field strength in the image volume. The field coils also include bucking or shielding coils that reduce the fringe fields outside the magnet. The coils are placed to minimize the peak-to-peak magnetic field variations or field harmonics combinations in the specified image volumes. By minimizing these parameters to an acceptable level, the homogeneity requirements are met.

Magnets usually have passive shims and/or sets of shimming correction coils that correct certain amounts of field errors or harmonics. The harmonics are mainly due to manufacturing tolerances and errors that deviate from the design. The shimming process is a necessary step to achieve the specified homogeneity for a practically manufactured magnet. A method of shimming a magnet having correction coils is disclosed, for example, in U.S. Pat. No. 5,006,804 to Dorri et al.

In the traditional MRI magnet design, the designed field homogeneity is achieved by optimizing the geometry of only the main and bucking coils. During this design process, both higher and lower order harmonics are minimized. Correction coils are used only for correcting the field errors that represent mainly lower order harmonics.

During the design of a magnet, the goal of meeting the target homogeneity is often challenging. The challenge results from the constraints of the physical dimensions allowed for the field coils, weight and cost considerations, etc. Meeting the target homogeneity is especially challenging when the homogeneity is required at more than one volume simultaneously. When meeting the requirement at a large volume, the homogeneity at the small volume is often sacrificed. The difficulty results from stringent constraints and the limited number of degrees of freedom from the field coils.

### SUMMARY OF INVENTION

In response to the above problems, an improved method of designing a magnetic resonance imaging magnet is provided. In accordance with one aspect, at least one set of correction coils is provided, preferably four or more. The coils are positioned about, and spaced along, the axial imaging bore formed by a magnet assembly, which receives patients. The set of correction coils are used to reduce lower order harmonics generated by the magnet. Reduction of the harmonics improves the homogeneity of the magnetic field at selected volumes around the magnet. The designed magnet may have a field strength of 0.5-3.0 Tesla, for example 1.5 Tesla. Preferably, the magnet has a design peak-to-peak magnetic field inhomogeneity of less than 10 parts per million. A typical cylindrical imaging volume for the magnet is between 20 to 50 cm in diameter.

The method may be used to design various types of magnets used in magnetic resonance imaging. Such magnets include a superconducting magnet, a shim coil system, and a gradient coil system. The magnet may be designed to have its longitudinal axis lie in a horizontal or a vertical plane. The correction coils can be the same correction coils that are used for shimming. Shimming correction coils are usually very powerful in correcting lower order harmonics (LOH). Small volume homogeneity is primarily affected by LOH due to physics and the nature of the mathematical harmonics expansion. In this way, the small volume homogeneity is easily achievable. The cost of the entire magnet system is also reduced, because additional coils are not required.

In accordance with another aspect of the invention, one correction coil, preferably four or more, is positioned about the axial bore. The correction coil or coils are used to reduce first and second order harmonics generated by the magnet to improve homogeneity of the magnetic field at more than one selected volume around the magnet.

In accordance with a further aspect of the invention, a method of designing a magnetic resonance imaging magnet for example, a superconducting magnet is provided. The magnet includes an axial imaging bore to receive patients and main magnet and bucking coils positioned at selected locations adjacent the axial bore. At least one correction coil, and preferably at least one set of correction coils, is positioned about the axial bore. Information is determined concerning the magnet to be designed including a desired peak-to-peak magnetic field value of the magnet. The information may concern the number of coils, the positions of the coils, the number of windings per coil, the direction of current for each coil, and the length of the magnet. The field strength in the bore of the magnet is measured at a predetermined number of points within a measurement volume. The measurement volume comprises large image volumes and small image volumes. The field inhomogeneity of the measurement volume is then determined. The peak-to-peak field measured between the highest and the lowest values of all the measured points is compared to the desired peak-to-peak magnetic field value. The locations of the main and bucking coils are adjusted to lower the peak-to-peak field throughout the measurement volume. The currents in the correction coil or set of correction coils are also adjusted to adjust lower order harmonics in the small image volumes. These steps are repeated until the field inhomogeneity of the measurement volume is less than or equal to the desired peak-to-peak magnetic field volume.

### BRIEF DESCRIPTION OF DRAWINGS

Other objects and features of the present invention will become apparent from the following detailed description considered in conjunction with the accompanying drawings. It should be understood, however, that the drawings are designed for the purpose of illustration only and not as a definition of the limits of the invention.

In the drawings, wherein similar reference characters denote similar elements throughout the several views:

FIG. 1 is a simplified schematic view of a magnetic resonance imaging magnet to be designed in accordance with the invention;

FIG. 2 is a partially cutaway isometric view of correction coils mounted on a cylindrical sleeve with an imaginary cylindrical grid situated inside the sleeve where field measurements are taken; and

FIG. 3 is a general flow chart for the magnet homogeneity design process in accordance with the present invention.

### DETAILED DESCRIPTION

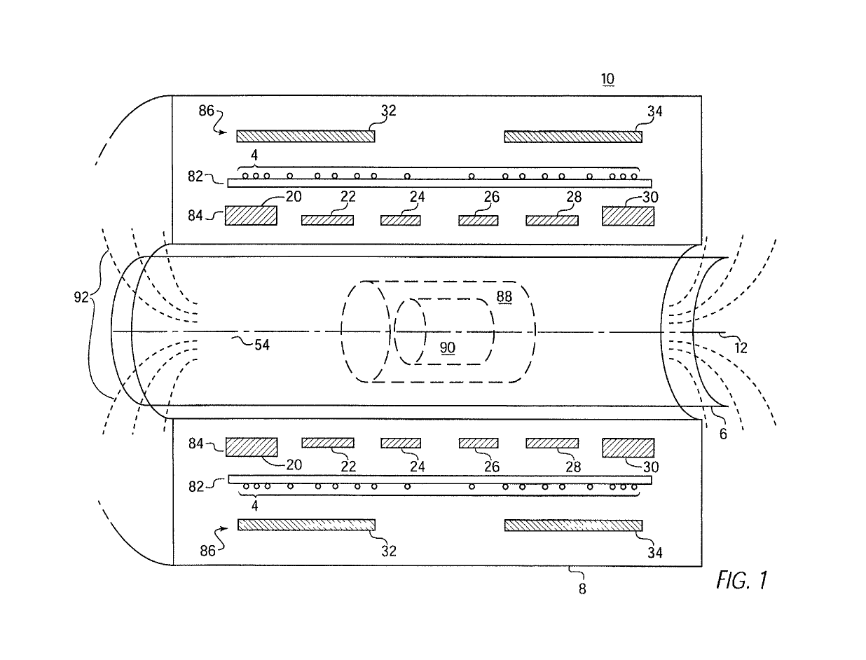

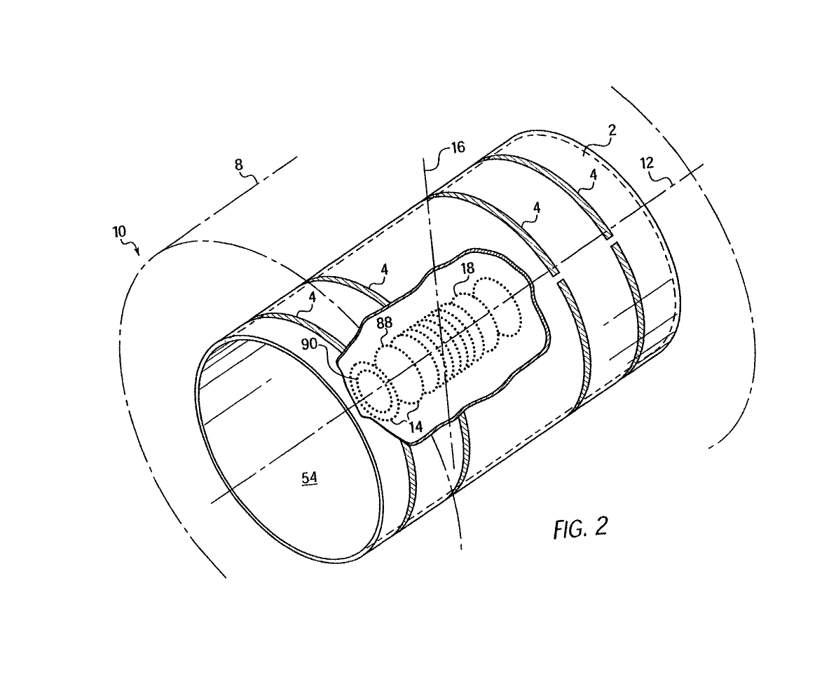

Referring to FIGS. 1 and 2, a correction coil assembly 82 including a plurality of correction coils 4 are shown mounted on a cylindrical sleeve 2 of nonmagnetic noncurrent conducting material. Sleeve 2 is positioned in a superconducting magnet 10. Preferably, four or more correction coils are used. The correction coils are preferably shimming coils, used to improve magnetic field homogeneity after construction of the magnet. A cryogen or helium pressure vessel 8 extends along and around axis 12 of imaging bore 6 formed within superconducting magnet 10. A main coil assembly 84 including a plurality of main magnet coils 20, 22, 24, 26, 28 and 30 are positioned within helium vessel 8 contiguous to and surrounding imaging bore 6. The coils are axially spaced along axis 12 and provide a magnet field indicated by flux lines 92. As is common in magnetic resonance imaging, the axial length of main magnet coils 20, 22, 24; and of 26, 28 and 30, respectively, are different. A bucking coil assembly 86 including one or more bucking or shielding coils such as those shown by coils 32 and 34 is included within helium vessel 8. The shielding coils reduce the magnetic stray field, and minimize siting and installation costs.

A series of measurement points are shown as dots 14 in FIG. 2. The center of the measured volume is coincident with the center of the bore. The center is at the intersection of the longitudinal axis with the center line 16 of an imaginary cylindrical volume 54 having a longitudinal axis which is aligned with the center of the bore. A series of imaginary circles 18 are spaced along the cylindrical volume. It should be understood that the image volume is not limited to being cylindrical. For example, the image volume may be a spherical or an elliptical volume.

The imaginary volume 54 may be considered to include a large image volume 88 and a small image volume 90. The magnet design residual harmonics resulting from optimizing the main and bucking coil geometry and positions includes both higher and lower order harmonics. The higher order harmonics dominate large volume inhomogeneity in image volume 88. The lower order harmonics contribute to small volume inhomogeneity in image volume 90. By using the harmonic capability of the correction coils in the design process, lower order harmonic corrections can be made. The lower order harmonic corrections modify the design residual harmonics and effectively correct small volume inhomogeneity.

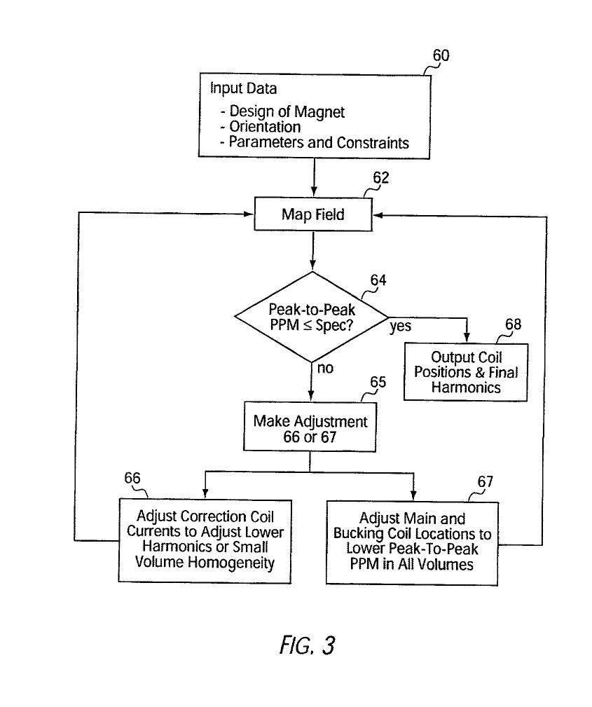

Referring now to FIG. 3, a flow chart showing the steps of the method of the present invention is shown. In the first step of the process, block 60, data is inputted to a computer system. The data includes (1) the type of magnet which is to be designed, e.g., a superconducting magnet; (2) the orientation of the magnet, e.g., whether the longitudinal axis of the magnet is to lie in a horizontal or vertical plane with a horizontal orientation, generally meaning that the coils of the magnet will be located at discrete locations along the magnet's longitudinal axis, and a vertical orientation generally meaning that the coils of the magnet will be in the form of nested solenoids; (3) the parameters of the system, e.g., the field strength in the image volume, the number of coils, the positions of the coils, the number of windings per coil, and the direction of current for each coil; and (4) the constraints on the system, e.g., the length of the magnet, the maximum current in the system, the desired value of the homogenous field B₀, and the desired location of the “5 gauss contour line” for shielded magnets. The inputted data will also normally include the configuration of the sample (e.g., patient) aperture (e.g., its dimensions and shape). The data also may include whether the magnet is to be shielded or not. Information may also be included regarding the minimum inter-coil spacing, the maximum number of windings per coil and wire thickness. Other similar information may be included depending on the particular magnet being designed.

The second step of the overall process, is represented in block 62. In this step, the field strength is measured at each of the measurement points to map the field in the base of the energized magnet. Next, in decision block 64, the peak-to-peak field measured between the highest and lowest values of all the mapped points is compared to the desired peak-to-peak field. If the peak-to-peak field is greater than desired, an adjustment is made (block 65). Usually the main and bucking coil locations as shown in block 67 are adjusted first. The field is then mapped in block 62, the peak-to-peak ppm inhomogeneity is evaluated and then the correction coil currents are adjusted in block 66 to adjust lower order harmonics or small volume inhomogeneity.

After the adjustment of the main and bucking coil locations as well as correction coil currents, the field is again mapped in block 62. The peak-to-peak ppm inhomogeneity is again evaluated. If the field still is more inhomogeneous than desired, as determined in block 64, the computer program in either blocks 66 or block 67 is run again, the field is mapped and the inhomogeneity evaluated iteratively, until the desired inhomogeneity in all volumes is met and the method has been completed (block 68).

Typically, the adjustment of the main and bucking coil locations in block 67 is done when the inhomogeneity is large. When the inhomogeneity is close to the desired value, the adjustment of the correction coil currents in block 66 is done until the method is completed.

Thus, in accordance with the improved design method, the field homogeneity is achieved not only by optimizing the main and bucking coil geometry and positions, but also by the reduction of lower order harmonics using correction coils. Therefore, the role of correction coils is expanded and becomes an integral part of the magnetic field homogeneity design.

As set forth above, the designed field homogeneity is determined by so-called residual field harmonics. The field homogeneity in large volumes is mainly controlled by higher order residual harmonics, while the field homogeneity in small volumes is mainly controlled by lower order residual harmonics. By integrating correction coils into magnet homogeneity optimization, a small amount of lower order harmonics can be present when minimizing the large volume peak-to-peak inhomogeneity. Therefore, one can concentrate on minimizing the higher order harmonics to improve the large volume homogeneity. The existence of a small amount of lower order harmonics does have a negative impact on the small volume homogeneity. However, the negative impact can be cancelled out by a proper choice of correction coils. In this way, both small volume and large volume homogeneity improvement is achieved. The improved magnetic field may have a design peak-to-peak magnetic field inhomogeneity of less than 10 parts per million in a cylindrical imaging volume between 20 to 50 cm. in diameter. The field strength of the magnet may be 0.5-3.0 Tesla.

As described above, the improved magnet homogeneity design process incorporates a set of correction coils. The capabilities of correction coils that can reduce lower order harmonics are considered in designing the small volume homogeneity. It then becomes easier to achieve the homogeneity requirements at small volumes. The small volume homogeneity is primarily affected by the existence of the lower order harmonics due to physics and the nature of the mathematical harmonics expansion. Lower order harmonics include first and second order harmonics, e.g. (1,0) (2,0) (or Z1, Z2 in other conventions).

The correction coils used in the design process can be the same correction coils that are used for shimming. Shimming correction coils are usually very powerful in correcting lower order harmonics. In this way, the small volume homogeneity is easily achievable. In addition, the cost of the entire magnet system is reduced, because additional costs are not required.

While preferred embodiments of the present invention have been shown and described, it is to be understood that many changes and modifications may be made thereunto without departing from the spirit and scope of the invention as defined in the appended claims.

1. A method of designing a magnetic resonance imaging magnet including an axial imaging bore to receive patients, comprising the steps of:
(a) providing at least one correction coil positioned about said axial bore; and
(b) using the correction coil to reduce lower order harmonics generated by the magnet to improve homogeneity of the magnetic field at selected volumes around the magnet.

2. The method according to claim 1 wherein the magnet is a superconducting magnet.

3. The method according to claim 1 wherein the correction coil comprises a shimming coil used to improve homogeneity of the magnetic field after construction of the magnet.

4. The method according to claim 1 wherein the improved magnetic field has a design peak-to-peak magnetic field inhomogeneity of less than 10 parts per million in a cylindrical, a spherical or an elliptical imaging volume between 20 to 50 cm. in diameter.

5. The method according to claim 1 wherein the magnet comprises at least six main magnet coils.

6. The method according to claim 1 wherein the magnet has a longitudinal axis disposed to lie in a horizontal plane or a vertical plane.

7. The method according to claim 1 wherein the magnet has a field strength of 0.5-3.0 Tesla.

8. A method of designing a superconducting magnetic resonance imaging magnet including an axial imaging bore to receive patients, comprising the steps of:
(a) providing at least one set of correction coils positioned about, and spaced along, said axial bore; and
(b) using the set of correction coils to reduce first and second order harmonics generated by the magnet to improve homogeneity of the magnetic field at more than one selected volume around the magnet.

9. The method according to claim 8 wherein the set of correction coils comprise shimming coils used to improve homogeneity of the magnetic field after construction of the magnet.

10. The method according to claim 8 wherein the magnetic field has a design peak-to-peak magnetic field inhomogeneity of less than 10 parts per million in a cylindrical, a spherical or an elliptical imaging volume between 20 to 50 cm. in diameter.

11. The method according to claim 8 wherein the magnet comprises at least six main magnet coils.

12. The method according to claim 8 wherein the magnet has a longitudinal axis disposed to lie in a horizontal plane or a vertical plane.

13. The method according to claim 8 wherein the magnet has a field strength of 0.5-3.0 Tesla.

14. A method of designing a magnetic resonance imaging magnet including an axial imaging bore to receive patients, main magnet and bucking coils positioned at selected locations adjacent said axial bore and at least one correction coil positioned about said axial bore, said method comprising the steps of:
(a) determining information concerning the magnet to be designed including a desired peak-to-peak magnetic field value of the magnet;
(b) measuring the field strength in the bore of the magnet at a predetermined number of points within a measurement volume comprising a large image volume and a small image volume;
(c) determining the field inhomogeneity of the measurement volume by comparing the peak-to-peak field measured between the highest and lowest values of all the measured points to the desired peak-to-peak magnetic field value;
(d) adjusting the locations of the main and bucking coils to lower the peak-to-peak field throughout the measurement volume;
(e) adjusting the currents in the correction coil to adjust lower order harmonics in the small image volume; and
(f) repeating steps (c), (d) and (e) until the field inhomogeneity of the measurement volume is less than or equal to the desired peak-to-peak magnetic field volume.

15. A method of designing a magnetic resonance imaging magnet including an axial imaging bore to receive patients, main magnet and bucking coils positioned at selected locations adjacent said axial bore, and at least one correction coil positioned about said axial bore, said magnet having a longitudinal axis disposed to lie in a horizontal plane, said method comprising the steps of:
(a) determining information concerning the magnet to be designed selected from the group consisting of the number of coils, the positions of the coils, the number of windings per coil, the direction of current for each coil and the length of the magnet, said information including a desired peak-to-peak magnetic field value of the magnet;
(b) measuring the field strength in the bore of the magnet at a predetermined number of points within a measurement volume comprising a large image volume and a small image volume;
(c) determining the field inhomogeneity of the measurement volume by comparing the peak-to-peak field measured between the highest and lowest values of all the measured points to the desired peak-to-peak magnetic field value;
(d) adjusting the locations of the main and bucking coils to lower the peak-to-peak field throughout the measurement volume;
(e) repeating step (c);
(f) adjusting the currents in the correction coil to adjust lower order harmonics in the small image volume; and
(g) repeating steps (c) and (f) until the field inhomogeneity of the measurement volume is less than or equal to the desired peak-to-peak magnetic field value.

16. A method of designing a superconducting magnetic resonance imaging magnet including an axial imaging bore to receive patients, main magnet and bucking coils positioned at selected locations adjacent said axial bore and at least one set of correction coils positioned about and spaced along said axial bore, said method comprising the steps of:
(a) determining information concerning the magnet to be designed including a desired peak-to-peak magnetic field value of the magnet;
(b) measuring the field strength in the bore of the magnet at a predetermined number of points within a measurement volume comprising a large image volume and a small image volume;
(c) determining the field inhomogeneity of the measurement volume by comparing the peak-to-peak field measured between the highest and lowest values of all the measured points to the desired peak-to-peak magnetic field value;
(d) adjusting the locations of the main and bucking coils to lower the peak-to-peak field throughout the measurement volume;
(e) adjusting the currents in the correction coils to adjust lower order harmonics in the small image volume; and
(f) repeating steps (c), (d) and (e) until the field inhomogeneity of the measurement volume is less than or equal to the desired peak-to-peak magnetic field volume.

17. A method of designing a superconducting magnetic resonance imaging magnet including an axial imaging bore to receive patients, main magnet and bucking coils positioned at selected locations adjacent said axial bore, and at least one set of correction coils positioned about and spaced along said axial bore, said magnet having a longitudinal axis disposed to lie in a horizontal plane, said method comprising the steps of:
(a) determining information concerning the magnet to be designed selected from the group consisting of the number of coils, the positions of the coils, the number of windings per coil, the direction of current for each coil and the length of the magnet, said information including a desired peak-to-peak magnetic field value of the magnet;
(b) measuring the field strength in the bore of the magnet at a predetermined number of points within a measurement volume comprising a large image volume and a small image volume;
(c) determining the field inhomogeneity of the measurement volume by comparing the peak-to-peak field measured between the highest and lowest values of all the measured points to the desired peak-to-peak magnetic field value;
(d) adjusting the locations of the main and bucking coils to lower the peak-to-peak field throughout the measurement volume;
(e) repeating step (c);
(f) adjusting the currents in the correction coils to adjust lower order harmonics in the small image volume; and
(g) repeating steps (c) and (f) until the field inhomogeneity of the measurement volume is less than or equal to the desired peak-to-peak magnetic field value.
